(19) United States
(12) Patent Application Publication
(10) Pub. No.: US 2014/0347834 A1
(43) Pub. Date: Nov. 27, 2014

(54) ELECTRONIC COMPONENT EMBEDDED PRINTED CIRCUIT BOARD AND METHOD FOR MANUFACTURING THE SAME

(71) Applicant: Samsung Electro-Mechanics Co., Ltd., Suwon (KR)

(72) Inventors: Seok Kyu LEE, Yeongi-gun (KR); Takayuki HAZE, Daejeon (KR); Soon Jin CHO, Cheongju (KR)

(73) Assignee: Samsung Electro-Mechanics Co., Ltd., Suwon (KR)

(21) Appl. No.: 14/285,882

(22) Filed: May 23, 2014

(30) Foreign Application Priority Data
May 24, 2013 (KR) 10-2013-0058965

(51) Int. Cl. H05K 1/18; H05K 1/03; H05K 3/30; H05K 1/02

(52) U.S. Cl. CPC H05K 1/187; H05K 1/0231; H05K 1/0306; H05K 1/036; H05K 3/30
USPC 361/762; 361/761; 361/763; 29/832

(57) ABSTRACT

An electronic component embedded printed circuit board and a method for manufacturing the same. The printed circuit board includes: a core having a cavity formed therein; an electronic component unit embedded in the cavity, including a plurality of electronic components, and having a coating layer formed on an outer peripheral surface of the electronic component unit to fix the plurality of electronic components; and an insulating layer laminated at least on the top of the core. An outer layer circuit pattern may be formed on the insulating layer.

### CROSS-REFERENCE TO RELATED APPLICATIONS

This application claims the foreign priority benefit under 35 U.S.C. Section 119 of Korean Patent Application Serial No. 10-2013-0058965, filed on May 24, 2013, in the Korean Intellectual Property Office, which is hereby incorporated by reference in its entirety into this application.

### BACKGROUND

1. Field

Embodiments of the present invention relate to an electronic component embedded printed circuit board and a method for manufacturing the same.

2. Description of the Related Art

As the size of substrates are limited and multiple functions of electronic devices are required with the miniaturization and thinning of IT electronic devices, such as mobile phones, there is a need to mount electronic components for implementing more functions in the limited area of substrates.

However, as the size of a substrate is limited, since it is not possible to secure a sufficient mounting area of the electronic components, there is a demand for technologies for inserting electronic components such as active devices like ICs and semiconductor chips and passive devices in a substrate, and technologies for embedding active devices and passive devices in the same layer or embedding electronic components in a substrate by stacking them have been developed.

In recent times, as high performance is required according to the popularization of devices such as smartphones having video conferencing and LTE technology, tablet PCs, etc. and the high speed signal transmission is frequent, a technology of embedding two or more electronic components such as MLCCs, which reduce the distortion and noise of the transmitted signals in transmitting a large amount of data, rather than only one electronic component, is needed.

In order to embed a plurality of electronic components as mentioned above, a cavity (space) for embedding one or more electronic components is required to be formed in a core of a substrate, and various types of defects may occur in the process of attaching a carrier (tape, film) for fixing the electronic component to the bottom of the cavity, fixing the electronic component, forming an insulating layer thereon, or removing the carrier.

### CITATIONS

Japanese Patent Laid-open Publication No. 2009-070938

### SUMMARY

One aspect of the present invention is to overcome the above-described problems and to provide an electronic component embedded printed circuit board that can improve productivity and product yield by embedding a plurality of electronic components as one unit.

Another aspect of the present invention is to provide a method for manufacturing an electronic component embedded printed circuit board that can improve productivity and product yield by embedding a plurality of electronic components as one unit.

In accordance with one aspect of the present invention, there is provided an electronic component embedded printed circuit board including: a core having a cavity formed therein; an electronic component unit embedded in the cavity and having a coating layer formed on the outer peripheral surface thereof to fix a plurality of electronic components; insulating layers laminated on the top and bottom of the core having the electronic component unit embedded therein; and outer layer circuit patterns formed on the insulating layers.

The electronic component unit may include two or more bonded electronic components which are horizontally or vertically arranged at predetermined intervals in the coating layer.

The core may be formed by impregnating a fabric with an epoxy material or impregnating a fabric with a glass material.

Meanwhile, the coating layer of the electronic component unit may be made of an organic/inorganic composite resin and the electronic components are bonded at predetermined intervals by the coating layer, wherein the coating layer may be formed on the top and bottom surfaces of the electronic components or formed to cover the entire surface of the electronic components.

And, the organic/inorganic composite resin may prepared by including a filler in a polymer resin, wherein the polymer resin may be a resin material mixed with one or more resins selected from epoxy, BT resins, acryl, polyimide (PI), polystyrene (PS), polyethersulfone (PES), and liquid crystal polymer (LCP)and the impregnated filler is an inorganic ceramic filler selected from SiO₂, Ba₂SO₄, and Ralc.

And, the surface of the coating layer of the electronic component unit may have a microroughness in the range of about 0.01 to about 0.99 μm.

Meanwhile, in accordance with another aspect of the present invention, there is provided a method for manufacturing an electronic component embedded printed circuit board, including: forming a cavity in a core and attaching a carrier to the bottom surface of the core; inserting an electronic component unit having a plurality of electronic components fixed by a coating layer in the cavity; forming an upper insulating layer on the top of the core having the electronic component unit embedded therein; removing the carrier attached to the bottom surface of the core; forming a lower insulating layer on the opposite surface of the core having the upper insulating layer formed thereon; and forming a via in the upper and lower insulating layers and forming outer layer circuit patterns which are electrically connected to the plurality of electronic components constituting the electronic component unit through the via.

In accordance with another aspect of the present invention, an electronic component embedded printed circuit board includes: a core having a cavity formed therein; an electronic component unit embedded in the cavity, comprising a plurality of electronic components and a coating layer encapsulating the plurality of electronic components; and an insulating layer laminated at least on a top of the core.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of an electronic component embedded printed circuit board in accordance with an embodiment of the present invention;

FIG. 2 is a cross-sectional view of an electronic component unit embedded in the printed circuit board in accordance with an embodiment of the present invention; and

FIG. 3A through 3G are a process diagrams of an embodiment of a method for manufacturing an electronic component embedded printed circuit board in accordance with the present invention.

### DESCRIPTION OF EMBODIMENTS

A matter regarding to an operational effect including a technical configuration for an object of an electronic component embedded printed circuit board and a method of manufacturing the same in accordance with the present invention will be clearly appreciated through the following detailed description with reference to the accompanying drawings showing embodiments of the present invention.

### Electronic Component Embedded Printed Circuit Board

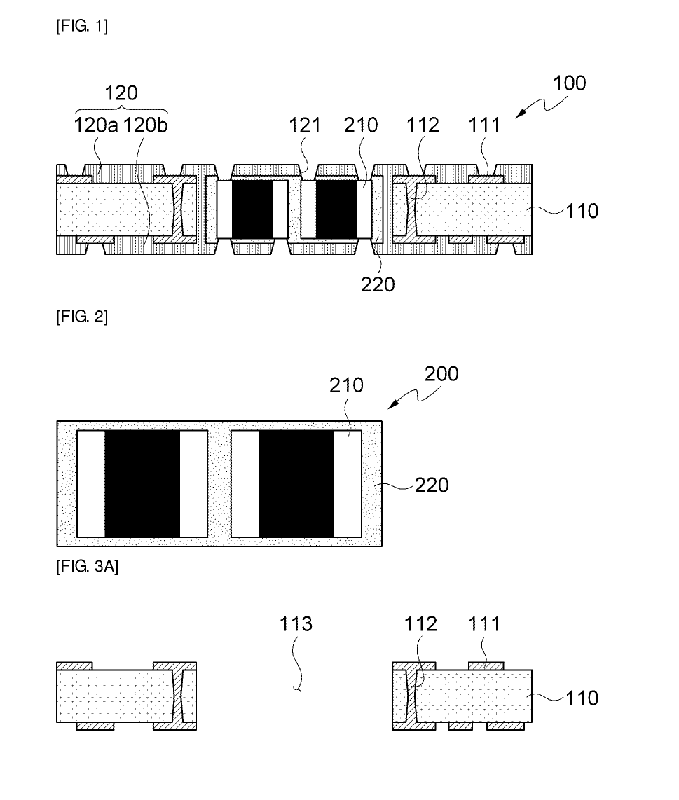

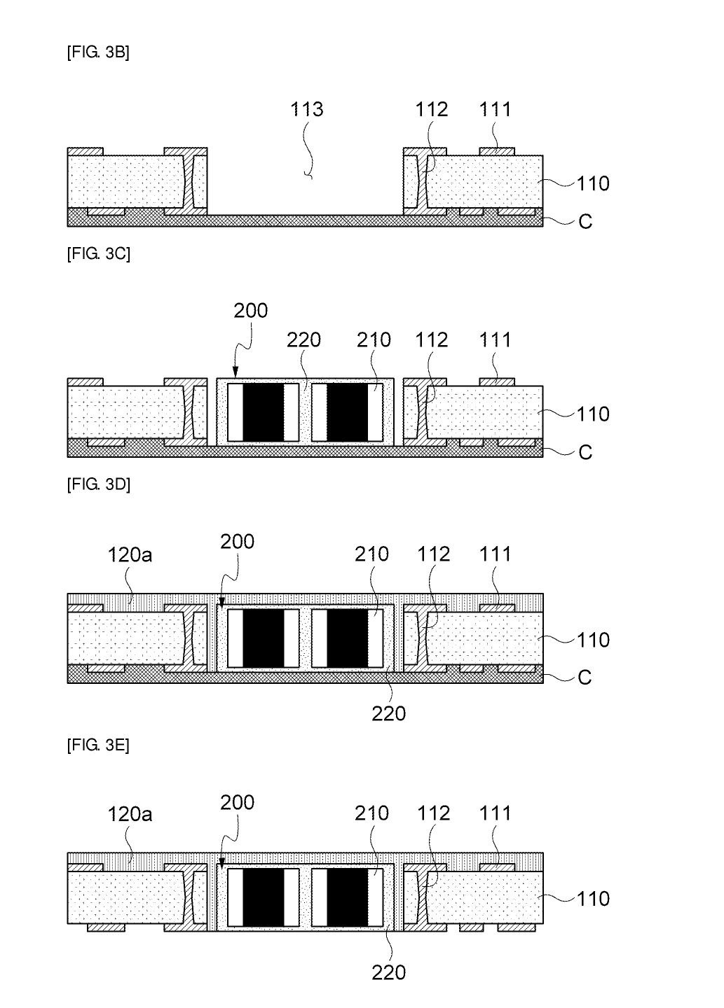

First, FIG. 1 is a cross-sectional view of an electronic component embedded printed circuit board in accordance with an embodiment of the present invention, and FIG. 2 is a cross-sectional view of an electronic component unit embedded in the printed circuit board in accordance with an embodiment of the present invention.

As shown, an electronic component embedded printed circuit board 100 in accordance with an embodiment of the present invention may include a core 110 having a cavity 113, an electronic component unit 200 embedded in the cavity 113 and having a plurality of horizontally connected electronic components 210; an insulating layer 120 laminated on the top and bottom of the core 110; and an outer layer circuit pattern (not shown in the drawing) formed on the insulating layer 120.

In the electronic component embedded printed circuit board 100, although it is shown that the electronic component unit 200 embedded in the core 110 is embedded in one place, without being limited thereto, it means that the electronic component unit 200 is embedded in a printed circuit board of each unit at regular intervals.

The core 110 may be made of an insulating material and may have inner layer circuit patterns 111 patterned on top and bottom surfaces thereof. The inner layer circuit patterns 111 may be electrically conducted to the outer layer circuit patterns of the insulating layers 120a and 120b through a via hole or a through hole 112 formed through the core 110. Further, the core 110, which is made of an insulating material, may be formed by impregnating a fabric with an epoxy material or impregnating a fabric with a glass material to improve strength. The cavity 113 may be formed to pass through the top and bottom of the core 110. The cavity 113 may be formed to pass through the top and bottom of the core 110 by mechanical drilling or laser drilling like a via. At this time, it is preferred that the cavity 113 is formed to have a width equal to or greater than that of the electronic component unit 200 inserted therein. And since the electronic component unit 200 inserted in the cavity 113 has a structure in which the plurality of electronic components 210 are connected to each other unlike the prior art, the cavity 113 can be formed wider than the prior art.

Meanwhile, as shown in FIG. 2, the plurality of electronic components 210 of the electronic component unit 200 inserted and embedded in the cavity 113 of the core 110 may be arranged at predetermined intervals, and a coating layer 220 may be formed on the outer peripheral surface of the plurality of electronic components 210. The coating layer 220 may play a role of fixing and maintaining the plurality of electronic components 210 horizontally at regular intervals and may be made of an organic/inorganic composite resin. At this time, the coating layer 220 may be formed only on the top and bottom surfaces of the electronic components 210 or on the entire surface including the side surface of the electronic components 210. Here, the electronic components 210 horizontally arranged by the coating layer 220 may be active devices such as IC, semiconductor chips, and CPU in addition to passive devices such as multi-layer ceramic capacitors (MLCCs) and low temperature co-fired ceramic (LTCC) devices.

Here, when the coating layer 220 is formed on the top and bottom surfaces of the electronic components 210, the organic/inorganic composite resin is coated on the top and bottom surfaces of the plurality of electronic components 210 which are arranged horizontally through thermal compression by top and bottom pressing so that the coating layer 220 can be formed only on the top and bottom surfaces of the electronic components 210. And when the coating layer 220 is formed on the entire surface of the electronic components 210, the coating layer 220 is formed to cover the entire outer peripheral surface of the electronic components 210 by applying and curing the organic/inorganic composite resin on the entire surface of the plurality of electronic components 210, which are maintained horizontally, and maintaining the organic/inorganic composite resin with a predetermined thickness by chemical desmearing. At this time, it is preferred that the height of the electronic component unit 200 in which the coating layer 220 covers the plurality of electronic components 210 is equal to or lower than the height of the core 110.

The coating layer 220 has a CTE, that is, a coefficient of thermal expansion, by curing of the organic/inorganic composite resin. It is preferred that the organic/inorganic composite resin material and containing materials of the coating layer 220 are adjusted to obtain a CTE similar to that of the core 110. Accordingly, the electronic component unit 200 in which the plurality of electronic components 210 are covered with the coating layer 210 can be embedded in the cavity 113 of the core 110 to have the same direction and degree of bending when the core 110 is bent.

Further, the organic/inorganic composite resin, which constitutes the coating layer 220 of the electronic component unit 200, may be prepared by including a filler in a polymer resin. Typically, the polymer resin may be a resin material mixed with one or more polymer resins selected from epoxy, BT, acryl, PI, PS, PES, and LCP, and the filler included in the organic/inorganic composite resin may be an inorganic ceramic filler selected from SiO₂, Ba₂SO₄, and Ralc. At this time, the content of the filler impregnated in the resin material constituting the organic/inorganic composite resin may be about 20 wt % to about 60 wt %.

And, two or more electronic components 210, which constitute the electronic component unit 200, may be fixed by the coating layer 220 to be embedded in the core 110 at regular intervals according to the design specifications of the electronic component embedded in the printed circuit board.

Further, a roughness may be formed on the surface of the coating layer 220 of the electronic component unit 200. The roughness may be a microroughness formed on the film of the coating layer 220, and it is preferred that the roughness Ra is formed in the range of 0.01 to 0.99 μm. It is possible to improve adhesion with the insulating layers 120a and 120b by the roughness formed on the surface of the coating layer 220 of the electronic component unit 200.

Meanwhile, the insulating layers 120a and 120b may be laminated on the top and bottom surfaces of the core 110 in which the electronic component unit 200 is embedded in the cavity 113. The insulating layers 120a and 120b may be made of prepreg consisting of an epoxy resin material and silica or an ABF film. As described above, since the organic/inorganic composite material, which constitutes the coating layer 220 of the electronic component unit 200 embedded in the cavity 113 of the core 110, is the same/similar material as the insulating layers 120a and 120b, it is possible to secure high adhesion on the adhesive interface between the coating layer 220 and the insulating layers 120a and 120b and perform stable via processing design and good copper plating when processing a via using laser.

The outer layer circuit patterns may be formed on the insulating layers 120a and 120b. The outer layer circuit patterns may be electrically connected to the inner layer circuit patterns 111 formed on the core 110 through vias 121 formed in the insulating layers 120a and 120b. This outer layer circuit pattern may be regarded as an inner layer circuit pattern again when another insulating layer is further built up on the insulating layer 120 and electrically connected to the pattern on the finally formed outermost insulating layer through the vias.

Further, among the vias 121, the via 121 formed in the insertion position of an MLCC, which is a passive device constituting the electronic component unit 200, electrically connects the outer layer circuit pattern and an external electrode of the MLCC and in contact with the external electrode of the MLCC through the insulating layers 120a and 120b and the coating layer 220 of the electronic component unit 200.

The connection of the patterns between the core 110 and the insulating layer 120 and between the insulating layers may be typically performed through the via 121, and the vias may be typically formed by mechanical drilling using CNC or laser drilling.

The printed circuit board 100 of the present embodiment configured as above can improve productivity compared to the prior art in which one electronic component is inserted in the cavity by forming the coating layer on the outer peripheral surface of the plurality of passive devices, typically such as MLCCs, and embedding the passive devices in the core and prevent a dimple phenomenon that the insulating layer is depressed between the electronic components by easily embedding the electronic components than the case in which one electronic component is inserted and flattening the surface by the coating layer 220.

Although it is mainly described that the electronic component embedded printed circuit board in accordance with an embodiment of the present invention described above has a structure in which the electronic components 210 constituting the electronic component unit 200 embedded in the core 110 are horizontally arranged by the coating layer 220, when only the size of the printed circuit board is a main design target beyond the purpose of thinning the printed circuit board, the plurality of electronic components may be laminated vertically and the laminated electronic components may be fixed at regular intervals by the coating layer to be embedded in the cavity of the core. Of course, in this case, it is preferred that the thickness of the core is as large as the height of the laminated electronic components.

### Method for Manufacturing Electronic Component Embedded Printed Circuit Board

A method for manufacturing the electronic component embedded printed circuit board for embodiments of the present invention configured as above will be described with reference to the following drawings.

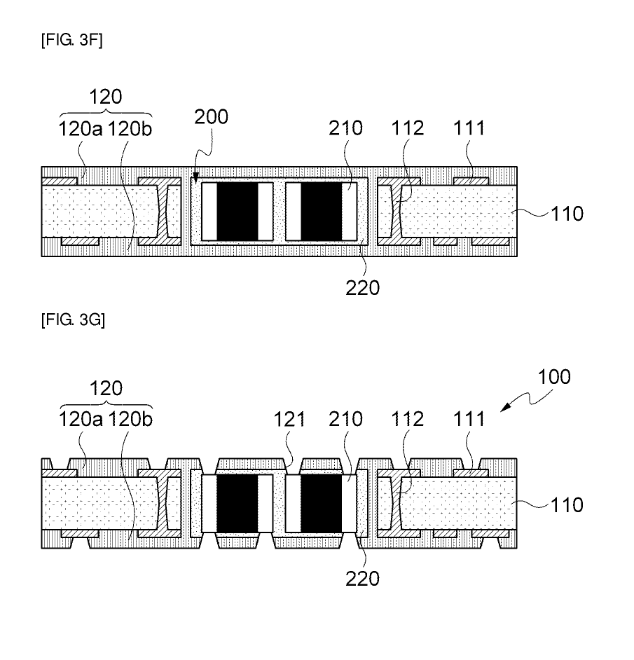

FIGS. 3A through 3G are process diagrams of an embodiment of a method for manufacturing an electronic component embedded printed circuit board in accordance with the present invention.

First, as shown in FIG. 3A, a through hole-shaped cavity 113 is formed in a core 110 which is made of an insulating material. The cavity 113 may be formed by laser processing or drilling. The cavity 113 is formed with a predetermined size and may be formed to have a width equal to or greater than the width of an electronic component unit 200 inserted therein. Further, predetermined circuit patterns 111 may be formed on top and bottom surfaces of the core 110. The circuit patterns 111 may be electrically connected to each other through a through hole 112.

Additionally, a carrier C may be attached to the bottom surface of the core 110 as in FIG. 3B. The carrier C is a member for fixing the position of the electronic component unit 200 when inserting the electronic component unit 200 in the cavity 113 formed as a through hole. The surface of the cavity 113 is coated with an adhesive material to prevent the electronic component unit 200 from being separated from the cavity 113 and temporarily fix the electronic component unit 200.

Next, as shown in FIG. 3C, the electronic component unit 200 is inserted in the cavity 113 of the core 110 to be positioned on the carrier C. It is preferred to insert the electronic component unit 200 whose total thickness including the thickness of a plurality of electronic components 210 and a coating layer 220 covering the outer peripheral surface of the electronic components 210 is the same as the thickness of the core 110. When the height of the electronic component unit 200 is higher than the height of the core 110, it is needed that the height of the electronic component 210 except the thickness of the outer coating layer 220 is not higher than the height of the core 110. This is to secure the sufficient thickness of an insulating layer 120 in terms of the characteristics of the printed circuit board, which becomes thinner, when laminating the insulating layer 120 after inserting the electronic component unit 200. Accordingly, it is possible to prevent disconnection of circuit patterns when forming the circuit pattern on each insulating layer and connecting the circuit patterns through a via.

Meanwhile, before inserting the electronic component unit 200 in the core 110, the plurality of electronic components 210 are arranged horizontally and the outer peripheral surface thereof is fixed by the coating layer 220 using an organic/inorganic composite resin. That is, referring to FIGS. 1 and 2, the organic/inorganic composite resin coating layer 220, which covers the outer peripheral surface of the electronic components 210, may be formed on the entire outer peripheral surface of the electronic components 210 or on the top and bottom surfaces of the electronic components 210.

When the coating layer 220 is formed on the top and bottom surfaces of the electronic components 210, the coating layer 220 is formed by coating the organic/inorganic composite resin on the top and bottom surfaces of the electronic components 210 and performing thermal compression using a press, and when the coating layer 220 is formed on the entire surface of the electronic components 210, the coating layer 220 is formed with a predetermined thickness by curing the organic/inorganic composite resin on the entire outer peripheral surface of the electronic components 210 and performing chemical desmearing. At this time, during the chemical desmearing of the coating layer 220, a predetermined microroughness may be formed on the surface film of the coating layer 220. Here, when forming the coating layer on the entire or a part of the surface of the electronic components 210, the organic/inorganic composite resin coating layer 220 may be formed to cover the surface of the electronic components 210 by horizontally positioning the plurality of electronic components 210 in a specific frame and injecting the organic/inorganic composite resin between the electronic components 210.

At this time, it is preferred that the organic/inorganic composite resin constituting the coating layer 220 has the same/similar CTE as the core 110 by containing a predetermined amount of filler in a resin material mixed with one or more polymer resins selected from epoxy, BT resins, acryl, polyimide (PI), polystyrene (PS), polyethersulfone (PES), and liquid crystal polymer (LCP), and the organic/inorganic composite resin has a CTE similar to that of the insulating layer 120, which will be described later, to improve bonding reliability and bending characteristics.

Next, as shown in FIG. 3D, an upper insulating layer 120a may be formed on the top of the core 110 having the electronic component unit 200 therein. At this time, a film type carrier C is attached to the bottom of the core 110 to fix the electronic component unit 200 inserted in the cavity 113 during the curing time of the upper insulating layer 120a. The upper insulating layer 120a may employ prepreg, which is the same/similar material as the organic/inorganic composite resin constituting the coating layer 220 of the electronic component unit 200, or an ABF film and may be cured by heating and pressing an insulating material after being laminated on the top of the core 110. Some of the insulating material or some of the adhesive material included in the prepreg such as epoxy or resin are introduced and cured in the space formed between the cavity 113 of the core 110 and the electronic component unit 200 to fix the electronic component unit 200 when heating and pressing the insulating material. Apart from this, before forming the upper insulating layer 120a, a separate adhesive may be injected between the side surface of the electronic component unit 200 and the sidewall of the cavity 113 to fix the electronic component unit 200.

And, when the lamination of the upper insulating layer 120a is completed, the carrier C attached to the bottom surface of the core 110 is removed as in FIG. 3E. After that, as in FIG. 3F, the core 110 is reversed, and a lower insulating layer 120b is laminated on the opposite surface of the core 110 having the upper insulating layer 120a thereon in the same manner as the upper insulating layer 120a and cured by heating and pressing to complete the formation of the insulating layers 120a and 120b.

Finally, as in FIG. 3G, via holes 121 are formed in the upper and lower insulating layers 120a and 120b, a plating layer is formed inside the via holes 121 and on the insulating layers 120a and 120b, and outer layer circuit patterns are formed by etching the plating layer to complete the manufacture of the electronic component embedded printed circuit board. At this time, the via hole 121 may be formed by mechanical or laser drilling like the cavity 113. Since the coating layer 220 of the electronic component unit 200 is made of the same/similar material as the insulating layer 120, it is possible to form the via hole 121 in the same drilling conditions without being disturbed by the bonding interface between the coating layer 220 and the insulating layer 120.

As described above, the electronic component embedded printed circuit board and the method for manufacturing the same in accordance with the present invention can improve productivity compared to the prior art in which one electronic component is inserted in the cavity by forming the coating layer on the outer peripheral surface of the plurality of electronic components and embedding the electronic components in the core and prevent deviation of the electronic components or voids between the electronic components and a dimple phenomenon that the insulating layer is depressed due to deviation or voids.

Further, the present invention can reduce manufacturing costs by embedding the plurality of electronic components in the form of one unit to simplify manufacturing processes and can improve a product yield by sorting only the good components in advance to embed the good components in the core.

And, the present invention can bring the coating layer and the insulating layer in direct contact with each other by filling a part of the insulating layer in the cavity to be introduced into the space between the electronic component unit embedded in the cavity and the sidewall of the cavity when forming the insulating layer, thereby improving the adhesion between the insulating layer and the electronic component unit.

The term “entire surface,” when used to describe the surface on which the coating layer is formed, does not exclude, for example, the absence of the coating layer at certain areas for purposes of connection elements such as via holes.

The above-described embodiments of the present invention are disclosed for the purpose of exemplification and it will be appreciated by those skilled in the art that various substitutions, modifications and variations may be made in these embodiments without departing from the technical spirit of the present invention. Such substitutions and modifications are intended to be included in the appended claims.

What is claimed is:

1. An electronic component embedded printed circuit board comprising:
a core having a cavity formed therein;
an electronic component unit embedded in the cavity, comprising a plurality of electronic components, and having a coating layer formed on an outer peripheral surface of the electronic component unit to fix the plurality of electronic components;
an insulating layer laminated at least on a top of the core; and
an outer layer circuit pattern formed on the insulating layer.

2. The electronic component embedded printed circuit board according to claim 1, wherein the electronic component unit comprises two or more electronic components horizontally or vertically arranged at regular intervals in the coating layer.

3. The electronic component embedded printed circuit board according to claim 2, wherein the coating layer is formed on top and bottom surfaces of the electronic components or is covering the entire surface of the electronic components.

4. The electronic component embedded printed circuit board according to claim 3, wherein the electronic components included in the electronic component unit are multi-layer ceramic capacitors (MLCCs).

5. The electronic component embedded printed circuit board according to claim 4, wherein the coating layer covers the entire surface of the electronic component unit and the ceramic capacitors (MLCCs) are insulated by the coating layer.

6. The electronic component embedded printed circuit board according to claim 4, further comprising:
a via to electrically connect the outer layer circuit pattern and an external electrode of one of the ceramic capacitors (MLCCs), the via being in contact with the external electrode through the insulating layer and the coating layer.

7. The electronic component embedded printed circuit board according to claim 3, wherein the insulating layer fills a space between the cavity and the electronic component unit embedded in the cavity so as to be in direct contact with the coating layer.

8. The electronic component embedded printed circuit board according to claim 2, wherein inner layer circuit patterns are patterned respectively on the top and bottom surfaces of the core and electrically connected to each other through a through hole formed through the core.

9. The electronic component embedded printed circuit board according to claim 8, wherein the core is formed by impregnating a fabric with an epoxy material or by impregnating a fabric with a glass material.

10. The electronic component embedded printed circuit board according to claim 1, wherein the cavity has a width equal to or greater than the width of the electronic component unit.

11. The electronic component embedded printed circuit board according to claim 1, wherein the coating layer of the electronic component unit is made of an organic/inorganic composite resin.

12. The electronic component embedded printed circuit board according to claim 11, wherein the organic/inorganic composite resin comprises a filler mixed with a polymer resin, wherein the polymer resin is a resin material mixed with one or more resins selected from epoxy, BT resins, acryl, polyimide (PI), polystyrene (PS), polyethersulfone (PES), and liquid crystal polymer (LCP).

13. The electronic component embedded printed circuit board according to claim 12, wherein the filler is an inorganic ceramic filler selected from SiO₂, Ba₂SO₄, and Ralc.

14. The electronic component embedded printed circuit board according to claim 13, wherein the content of the filler impregnated in the organic/inorganic composite resin is about 20 wt % to about 60 wt %.

15. The electronic component embedded printed circuit board according to claim 11, wherein the surface of the coating layer of the electronic component unit has a microroughness in the range of about 0.01 μm to about 0.99 μm.

16. A method for manufacturing an electronic component embedded printed circuit board, comprising:
forming a cavity in a core and attaching a carrier to a bottom surface of the core;
inserting an electronic component unit, having a plurality of electronic components fixed by a coating layer, into the cavity;
forming an upper insulating layer on top of the core;
detaching the carrier from the bottom surface of the core;
forming a lower insulating layer on a surface of the core opposite to the bottom surface; and
forming a via in the upper and lower insulating layers and forming outer layer circuit patterns that are electrically connected to the plurality of electronic components constituting the electronic component unit through the via.

17. The method for manufacturing an electronic component embedded printed circuit board according to claim 16, wherein in the forming the upper insulating layer, the electronic component unit is attached to the core through the upper insulating layer

18. The method for manufacturing an electronic component embedded printed circuit board according to claim 17, further comprising, before inserting the electronic component unit in the cavity, applying an adhesive member on a top surface of the carrier.

19. The method for manufacturing an electronic component embedded printed circuit board according to claim 17, further comprising, before inserting the electronic component unit in the cavity, horizontally arranging the plurality of electronic components and horizontally fixing the plurality of electronic components at predetermined intervals by coating an organic/inorganic composite resin on an outer peripheral surface of the electronic components to form the coating layer.

20. The method for manufacturing an electronic component embedded printed circuit board according to claim 19, wherein the coating layer is formed on top and bottom surfaces of the plurality of electronic components.

21. The method for manufacturing an electronic component embedded printed circuit board according to claim 19, wherein the coating layer is formed to cover the entire surface, including the top and bottom surfaces, of the plurality of electronic components.

22. The method for manufacturing an electronic component embedded printed circuit board according to claim 19, wherein fixing the plurality of electronic components by the coating layer further comprises forming the coating layer by applying the organic/inorganic composite resin on top and bottom surfaces of the electronic components and performing thermal compression using a press.

23. The method for manufacturing an electronic component embedded printed circuit board according to claim 19, wherein fixing the plurality of electronic components by the coating layer further comprises:
applying and curing the organic/inorganic composite resin on the entire outer peripheral surface of the plurality of electronic components with a predetermined thickness; and
forming the cured coating layer with a uniform thickness by chemical desmearing.

24. The method for manufacturing an electronic component embedded printed circuit board according to claim 22, further comprising, after fixing the plurality of electronic components by the coating layer, forming a microroughness on the surface of the coating layer by chemical desmearing.

25. The method for manufacturing an electronic component embedded printed circuit board according to claim 23, further comprising, after fixing the plurality of electronic components by the coating layer, forming a microroughness on the surface of the coating layer by chemical desmearing.

26. The method for manufacturing an electronic component embedded printed circuit board according to claim 22, wherein the organic/inorganic composite resin includes a filler in a resin material mixed with one or more polymer resins selected from epoxy, BT resins, acryl, polyimide (PI), polystyrene (PS), polyethersulfone (PES), and liquid crystal polymer (LCP) so as to have a coefficient of thermal expansion (CTE) equal or similar to those of the core and the insulating layer.

27. The method for manufacturing an electronic component embedded printed circuit board according to claim 23, wherein the organic/inorganic composite resin includes a filler in a resin material mixed with one or more polymer resins selected from epoxy, BT resins, acryl, PI (polyimide), PS (polystyrene), PES (polyethersulfone), and LCP (liquid crystal polymer) so as to have a coefficient of thermal expansion (CTE) equal or similar to those of the core and the insulating layer.

28. An electronic component embedded printed circuit board comprising:
a core having a cavity formed therein;
an electronic component unit embedded in the cavity, comprising a plurality of electronic components and a coating layer encapsulating the plurality of electronic components; and
an insulating layer laminated at least on a top of the core.

29. The electronic component embedded printed circuit board of claim 28, further comprising:
an inner layer circuit pattern formed on the core and under the insulating layer, and
an outer layer circuit pattern formed on the insulating layer and electrically connected to an electrode of at least one of the plurality of electronic components through a via in the insulating layer.

30. A method for manufacturing the electronic component embedded printed circuit board of claim 1, comprising:
forming the cavity in the core and attaching a carrier to a bottom surface of the core;
preparing the electronic component unit by fixing the plurality of electronic components with the coating layer, and then inserting the electronic component unit into the cavity;
forming the insulating layer on top of the core; and
detaching the carrier from the bottom surface of the core.
